(19) United States
(12) Patent Application Publication
(10) Pub. No.: US 2026/0059848 A1
(43) Pub. Date: Feb. 26, 2026

(54) INTEGRATED CIRCUIT DEVICE

(71) Applicant: Samsung Electronics Co., Ltd., Suwon-si (KR)

(72) Inventors: Hyunmin AHN, Suwon-si (KR); Soojin JEONG, Suwon-si (KR); Myunggil KANG, Suwon-si (KR); Wookhyun KWON, Suwon-si (KR); Bumcheol KIM, Suwon-si (KR); Byounghak HONG, Suwon-si (KR)

(73) Assignee: Samsung Electronics Co., Ltd., Suwon-si (KR)

(21) Appl. No.: 19/026,973

(22) Filed: Jan. 17, 2025

(30) Foreign Application Priority Data
Aug. 22, 2024 (KR) 10-2024-0113095

(51) Int. Cl. H10D 84/83; H10D 62/10; H10D 62/13; H10D 84/01

(52) U.S. Cl. CPC H10D 84/8311; H10D 62/116; H10D 62/151; H10D 84/8312; H10D 84/832; H10D 84/013

(57) ABSTRACT

Provided is an integrated circuit device including a plurality of semiconductor patterns having different widths. In order to minimize or reduce current leakage from a semiconductor pattern having a relatively small width to below a source/drain region, a lower thin film having a certain thickness may be selectively formed below the source/drain region corresponding to the narrow semiconductor pattern, thereby improving electrical reliability of the device. Also, provided is an integrated circuit device including a plurality of semiconductor patterns having different widths. In order to minimize or reduce current leakage from a semiconductor pattern having a relatively small width to below a source/drain region, a lower thin film may be selectively and thickly deposited below the source/drain region corresponding to the narrow semiconductor pattern, thereby improving electrical reliability of the device.

### CROSS-REFERENCE TO RELATED APPLICATION

This application is based on and claims priority under 35 U.S.C. § 119 to Korean Patent Application No. 10-2024-0113095, filed on Aug. 22, 2024, in the Korean Intellectual Property Office, the disclosure of which is incorporated by reference herein in its entirety.

### BACKGROUND

The inventive concepts relate to integrated circuit devices. More particularly, the inventive concepts relate to integrated circuit devices including a field effect transistor.

With the development of electronics technology, the demand for high integration of integrated circuit devices is increasing and the down-scaling is rapidly in progress. The down-scaling of integrated circuit devices causes short channel effects in transistors, which deteriorates the reliability of integrated circuit devices. In order to mitigate the short channel effects, integrated circuit devices that have multi-gate structures, such as nanosheet-type transistors, have been proposed.

### SUMMARY

The inventive concepts provide integrated circuit devices that have improved operation characteristics and/or improved reliability.

Also, the objects of the inventive concepts are not limited to the aforementioned objects, but other objects not described herein will be clearly understood by those skilled in the art from the following description.

In order to achieve the above objects, the inventive concepts provide integrated circuit devices as follows.

According to an aspect of the inventive concepts, there is provided an integrated circuit device including a fin-type active region protruding from a substrate and extending in a first direction; a first semiconductor pattern and a second semiconductor pattern spaced apart from each other in the first direction and a second direction, the second direction intersecting the first direction, the first semiconductor pattern and the second semiconductor pattern are above the fin-type active region; a gate line extending in the second direction, the gate line above the fin-type active region and surrounding the first and second semiconductor patterns; a first source/drain region and a second source/drain region adjacent to the gate line above the fin-type active region, the first source/drain region being connected to the first semiconductor pattern, the second source/drain region being connected to the second semiconductor pattern; and a lower thin film on the fin-type active region and below the first source/drain region in a third direction intersecting the first direction and the second direction, wherein the second semiconductor pattern has a greater width than the first semiconductor pattern in the second direction.

According to another aspect of the inventive concepts, there is provided an integrated circuit device including a fin-type active region protruding from a substrate and extending in a first direction; a first semiconductor pattern and a second semiconductor pattern spaced apart from each other in the first direction and a second direction, the second direction intersecting the first direction, the first semiconductor pattern and the second semiconductor pattern are above the fin-type active region; a gate line extending in the second direction above the fin-type active region and surrounding the first and second semiconductor patterns; a first source/drain region and a second source/drain region adjacent to the gate line above the fin-type active region, the first source/drain region being connected to the first semiconductor pattern, the second source/drain region being connected to the second semiconductor pattern; a first lower thin film on the fin-type active region and below the first source/drain region; and a second lower thin film on the fin-type active region and below the second source/drain region, wherein the second semiconductor pattern has a greater width than the first semiconductor pattern in the second direction, and the first lower thin film has a greater thickness in a third direction intersecting the first direction and the second direction than the second lower thin film.

According to another aspect of the inventive concepts, there is provided an integrated circuit device including a fin-type active region protruding from a substrate and extending in a first direction; a plurality of semiconductor patterns spaced apart from each other in the first direction and a second direction, the second direction intersecting the first direction, the plurality of semiconductor patterns are above the fin-type active region; a gate line extending in the second direction above the fin-type active region and surrounding each of the plurality of semiconductor patterns; a plurality of source/drain regions adjacent to the gate line above the fin-type active region and respectively connected to the plurality of semiconductor patterns; and a lower thin film on the fin-type active region and below at least one of the plurality of source/drain regions, wherein a semiconductor pattern adjacent to a source/drain region overlapping the lower thin film has a less width in the second direction than another semiconductor pattern not adjacent to the source/drain region overlapping the lower thin film.

### BRIEF DESCRIPTION OF THE DRAWINGS

Some example embodiments will be more clearly understood from the following detailed description taken in conjunction with the accompanying drawings in which:

FIG. 1 is a schematic layout view showing an integrated circuit device according to some example embodiments;

FIGS. 2 to 9B are cross-sectional views showing a method of manufacturing an integrated circuit device, according to some example embodiments; Specifically, FIGS. 2, 3A, 4, 5, 6, 7A, 8A, and 9A are cross-sectional views of the integrated circuit device corresponding to the cross-section taken along line A1-A1′ of FIG. 1, and FIGS. 3B, 7B, 8B, and 9B are cross-sectional views of the integrated circuit device corresponding to the cross-section taken along line A2-A2′ of FIG. 1;

FIGS. 10 to 13B are cross-sectional views showing a method of manufacturing an integrated circuit device, according to some example embodiments; Specifically, FIGS. 10, 11A, 12A, and 13A are cross-sectional views of the integrated circuit device corresponding to the cross-section taken along line A1-A1′ of FIG. 1, and FIGS. 11B, 12B, and 13B are cross-sectional views of the integrated circuit device corresponding to the cross-section taken along line A2-A2′ of FIG. 1;

FIGS. 14 to 17B are cross-sectional views showing a method of manufacturing an integrated circuit device, according to some example embodiments; and Specifically, FIGS. 14, 15A, 16A, and 17A are cross-sectional views of the integrated circuit device corresponding to the cross-section taken along line A1-A1′ of FIG. 1, and FIGS. 15B, 16B, and 17B are cross-sectional views of the integrated circuit device corresponding to the cross-section taken along line A2-A2′ of FIG. 1.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, some example embodiments are described in detail with reference to the accompanying drawings. The same reference numerals are given to the same elements in the drawings, and repeated descriptions thereof are omitted.

Since the disclosure may be diversely modified and have various example embodiments, some example embodiments are depicted in the drawings and described in detail in the detailed description. However, this is not intended to limit the scope to the example embodiments depicted, and it should be understood that the disclosure covers all the modifications, equivalents, and replacements within the idea and technical scope disclosed herein. In describing some example embodiments, when it is determined that a detailed description of the related known art may obscure the gist of the present disclosure, the detailed description thereof is omitted.

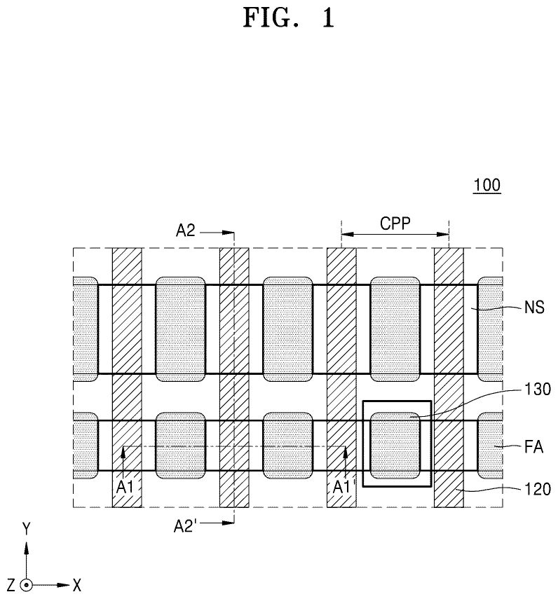

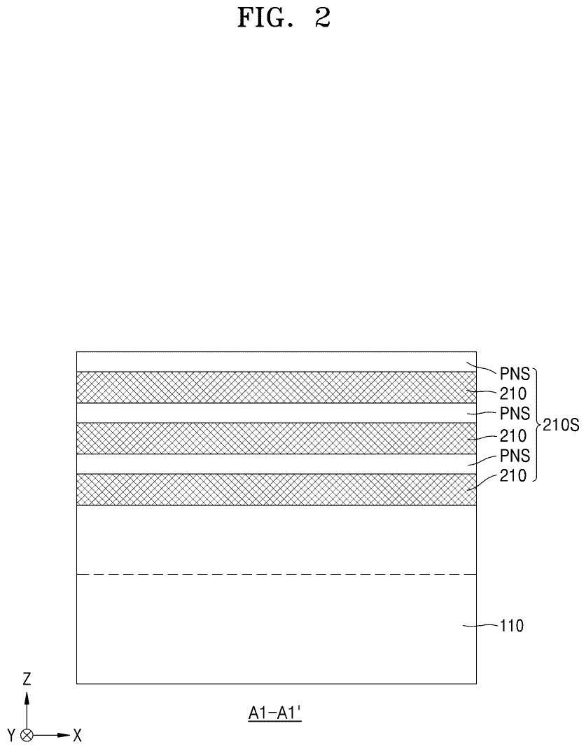

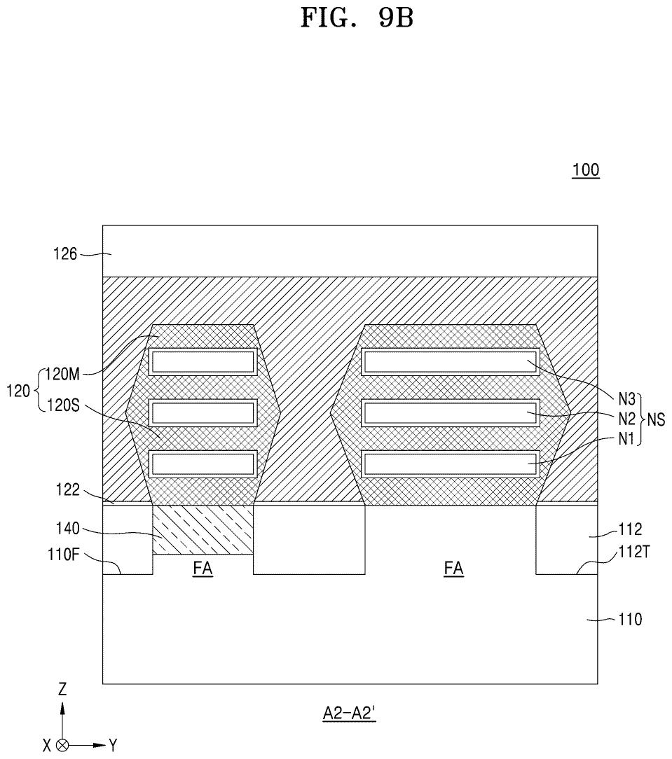

FIG. 1 is a schematic layout view showing an integrated circuit device 100 according to some example embodiments. FIG. 9A is a cross-sectional view of the integrated circuit device 100 taken along line A1-A1′ of FIG. 1, and FIG. 9B is a cross-sectional view of the integrated circuit device 100 taken along line A2-A2′ of FIG. 1.

Referring to FIG. 1, FIG. 9A, and FIG. 9B, the integrated circuit device 100 may include a transistor TRI formed on a substrate 110, and the transistor TRI may constitute a logic cell including a multi-bridge-channel field effect transistor (MBCFET) device. In some example embodiments, the transistor TRI may include a p-channel metal-oxide semiconductor (PMOS) transistor or an n-channel metal-oxide semiconductor (NMOS) transistor.

In some example embodiments, the substrate 110 may include group IV semiconductors, such as Si and Ge, group IV-IV compound semiconductors, such as SiGe and SiC, or group III-V compound semiconductors, such as GaAs, InAs, and/or InP. The substrate 110 has a first surface 110F, and a plurality of fin-type active regions FA may protrude from the first surface 110F and extend in a first horizontal direction (an X direction).

A device isolation film 112 may be disposed on the first surface 110F of the substrate 110 and cover the lower side of the sidewall of a fin-type active region FA. The device isolation film 112 may fill the inside of a device isolation trench 112T extending from the first surface 110F of the substrate 110 into the substrate 110 and may have, for example, a double layer structure of an interface layer (not shown) and a buried insulating layer (not shown).

In some example embodiments, a plurality of semiconductor patterns NS may be spaced apart from each other in a vertical direction (a Z direction) above the fin-type active region FA. In some example embodiments, the plurality of semiconductor patterns NS may each include group IV semiconductors, such as Si and/or Ge, group IV-IV compound semiconductors, such as SiGe and/or SiC, or group III-V compound semiconductors, such as GaAs, InAs, and/or InP.

The plurality of semiconductor patterns NS may each have a relatively large width in a second horizontal direction (a Y direction) and a relatively small thickness in the vertical direction (the Z direction), and may have, for example, a shape of a nanosheet. For example, as illustrated in FIG. 9A, the plurality of semiconductor patterns NS may include a first nanosheet N1, a second nanosheet N2, and a third nanosheet N3 that are spaced apart from each other in the vertical direction (the Z direction) above the fin-type active region FA. However, the number of the plurality of semiconductor patterns NS is not limited to that shown in FIG. 9A. Each of the plurality of semiconductor patterns NS may function as a channel region.

In some example embodiments, each of the plurality of semiconductor patterns NS may have the width of about 5 nm to about 100 nm in the second horizontal direction (the Y direction) and each of the plurality of semiconductor patterns NS may have the thickness of about 1 nm to about 10 nm in the vertical direction (the Z direction), but the example embodiments are not limited thereto. In some example embodiments, at least one semiconductor pattern NS among the plurality of semiconductor patterns NS may have a different thickness in the vertical direction (the Z direction) from the other semiconductor patterns NS.

In some example embodiments, the plurality of semiconductor patterns NS spaced apart from each other in the second horizontal direction (the Y direction) may have different widths in the second horizontal direction (the Y direction). For example, referring to FIG. 9B, the thickness of the semiconductor patterns NS formed on the left side in the second horizontal direction (the Y direction) may be approximately 10 nm, and the thickness of the semiconductor patterns NS formed on the right side in the second horizontal direction (the Y direction) may be approximately 30 nm. However, the inventive concepts are not limited thereto, and FIG. 9B shows only one example. The thickness of the semiconductor pattern NS in the second horizontal direction (the Y direction) may include different values in a range from about 5 nm to about 100 nm.

A plurality of gate lines 120 may extend in the second horizontal direction (the Y direction) to surround the plurality of semiconductor patterns NS and may be spaced apart from each other in the first horizontal direction (the X direction) by first gate intervals CPP.

In some example embodiments, the plurality of gate lines 120 may each include doped polysilicon, metal, conductive metal nitride, conductive metal carbide, conductive metal silicide, or a combination thereof. For example, the gate line 120 may include, but is not limited to, Al, Cu, Ti, Ta, W, Mo, TaN, NiSi, CoSi, TiN, WN, TiAl, TiAlN, TaCN, TaC, TaSiN, or a combination thereof. In some example embodiments, the plurality of gate lines 120 may include a work function metal-containing layer (not shown) and a gap-fill metal film (not shown). The work function metal-containing layer may include at least one metal selected from a group consisting of Ti, W, Ru, Nb, Mo, Hf, Ni, Co, Pt, Yb, Tb, Dy, Er, and/or Pd. The gap-fill metal film may include a W film or an Al film. In some example embodiments, the plurality of gate lines 120 may include a stack structure of TiAlC/TiN/W, a stack structure of TiN/TaN/TiAlC/TiN/W, or stack a structure of TiN/TaN/TiN/TiAlC/TiN/W, but the example embodiment is not limited thereto.

In some example embodiments, each of the plurality of gate lines 120 may include a main gate 120M covering the uppermost semiconductor pattern NS and a sub gate 120S positioned between two adjacent semiconductor patterns NS. For example, the main gate 120M may cover the upper surface of the third nanosheet N3, and the sub gates 120S may be located between the fin-type active region FA and the first nanosheet N1, between the first nanosheet N1 and the second nanosheet N2, and between the second nanosheet N2 and the third nanosheet N3.

A gate insulating layer 122 may be located between the plurality of gate lines 120 and the plurality of semiconductor patterns NS. For example, the gate insulating layer 122 may be located between the uppermost semiconductor pattern NS and the main gate 120M of each of the plurality of gate lines 120, between the sub gate 120S and each of the semiconductor patterns NS, and between the sub gate 120S and the upper surface of the fin-type active region FA and/or the upper surface of a lower thin film 140.

In some example embodiments, the gate insulating layer 122 may include a silicon oxide film, a silicon oxynitride film, a high-k dielectric film having a higher dielectric constant than the silicon oxide film, or a combination thereof. The high-k dielectric film may include metal oxide or metal oxynitride. For example, the high-k dielectric film that may be used as the gate insulating layer 122 may include, but is not limited to, HfO₂, HfSiO, HfSiON, HfTaO, HfTiO, HfZrO, ZrO₂, Al₂O₃, or a combination thereof.

An outer insulating spacer 124 may be located on the sidewall of the main gate 120M of each of the plurality of gate lines 120. The outer insulating spacers 124 may be respectively located on both ends of the uppermost semiconductor pattern NS and each may be spaced apart from the gate line 120 with the gate insulating layer 122 therebetween. In some example embodiments, the outer insulating spacer 124 may include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N₂), or a combination thereof.

A plurality of recesses RS1 and RS2 (or referred to as a plurality of recesses RS or first and second recesses RS1 and RS2) extending into the fin-type active region FA may be formed on both sides of the plurality of gate lines 120, and a plurality of source/drain regions 130 may be formed inside the plurality of recesses RS1 and RS2. The plurality of source/drain regions 130 may be respectively formed inside the plurality of recesses RS and may be connected to both ends of the plurality of semiconductor patterns NS.

In some example embodiments, the source/drain region 130 may include a buffer layer 132, a main semiconductor layer 134, and a capping layer 136. In some example embodiments, the buffer layer 132 may be located on the inner wall of each of the plurality of recesses RS and be in contact with the plurality of semiconductor patterns NS. The main semiconductor layer 134 may fill the interior of each of the plurality of recesses RS and may have the upper surface at a higher level than the uppermost semiconductor pattern NS. The capping layer 136 may cover the upper surface of the main semiconductor layer 134 and have a relatively small thickness.

In some example embodiments, the buffer layer 132 may be formed using a semiconductor material that includes a first element as a dopant. In some example embodiments, the first element may include at least one of fluorine, oxygen, argon, and/or nitrogen. In some example embodiments, the main semiconductor layer 134 may include at least one semiconductor material of SiGe, SiP, and/or SiGeB. The main semiconductor layer 134 may not include the first element as a dopant. In some example embodiments, the capping layer 136 may include a semiconductor material. For example, the capping layer 136 may include doped or undoped silicon. The capping layer 136 may cover the upper surface and sidewalls of the main semiconductor layer 134.

In some example embodiments, a lower thin film 140 may be formed below at least some of the plurality of source/drain regions 130. For example, referring to FIG. 9A, at least a portion of the first recess RS1 may be filled with the lower thin film 140, and the other portion thereof may be filled with the source/drain region 130, but the interior of the second recess RS2 may be completely filled with the source/drain region 130.

In some example embodiments, the lower thin film 140 may be formed by an epitaxy process. In some example embodiments, the lower thin film 140 may include undoped Si, SiB, SiN, or a combination thereof. In this specification, the lower thin film 140 is illustrated as a single layer. However, this is only an example, and it is obvious that the lower thin film 140 may be formed as a multi layer.

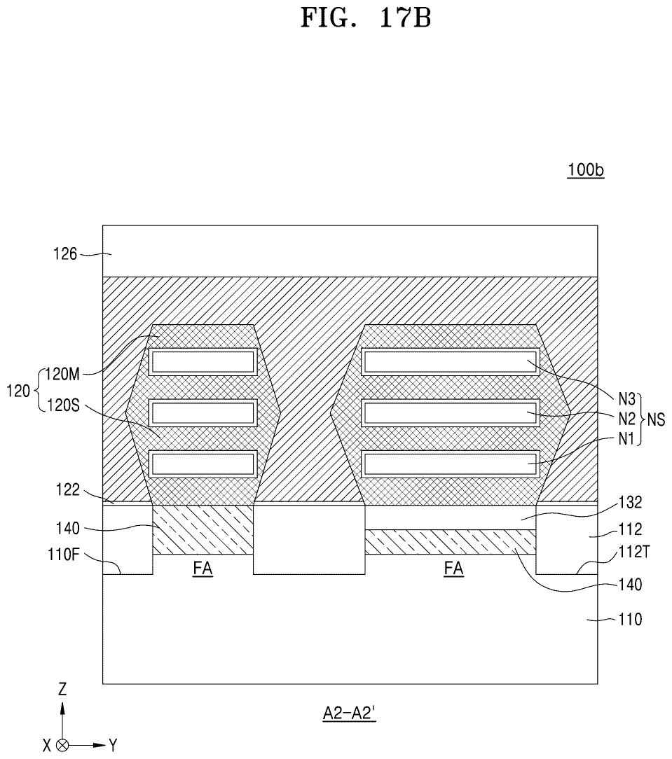

In some example embodiments, for example, referring to FIGS. 17A and 17B, lower thin films 140 may be formed below all of a plurality of source/drain regions 130. When the lower thin films 140 are formed in all of the recesses RS1 and RS2, the thicknesses of the lower thin films 140 in the vertical direction (the Z direction) may be different from each other depending on the widths of the semiconductor patterns NS in the second horizontal direction (the Y direction) which are formed on the lower thin films 140. For example, the thickness of the lower thin film 140 in the vertical direction (the Z direction) formed below a semiconductor pattern NS in a case in which the width of the semiconductor pattern NS in the second horizontal direction (the Y direction) is relatively large may be less than the thickness of the lower thin film 140 in the vertical direction (the Z direction) formed below a semiconductor pattern NS in a case in which the width of the semiconductor pattern NS in the second horizontal direction (the Y direction) is relatively small. Detailed descriptions of whether the lower thin film 140 is formed on the upper surface of the fin-type active regions FA and the thickness thereof are described below.

A gate capping layer 126 may be disposed on the plurality of gate lines 120 and the outer insulating spacer 124, and a passivation layer 142 and an inter-gate insulating layer 144 covering the source/drain region 130 may be formed between the plurality of gate lines 120. In some example embodiments, the passivation layer 142 and the inter-gate insulating layer 144 may each include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N₂), or a combination thereof.

Although not shown, a back-end-of-line (BEOL) structure may be disposed on the gate capping layer 126 and the inter-gate insulating layer 144. The BEOL structure may include a contact electrically connected to a source/drain region 130 and/or a gate line 120, a via connected to the contact, and a metal wire connected to the via.

In some example embodiments, a backside power delivery network may be further formed on the bottom surface of the substrate 110, and a connection structure, such as a via contact, may be further formed to connect the backside power delivery network to the upper surface of the source/drain region 130 or to connect the backside power delivery network to the lower surface of the source/drain region 130.

In general, in a multi-bridge channel-type field effect transistor device including a plurality of semiconductor patterns NS, the difficulty of processes of forming a gate line surrounding the plurality of semiconductor patterns NS is considerably high. In particular, in the process of replacing a sacrificial pattern between the plurality of semiconductor patterns with a gate line, electrical short-circuit between the source/drain region and the gate line are likely to occur. To this end, a method of forming an epitaxial film first below a source/drain region before forming the source/drain region has been proposed. However, in a device including semiconductor patterns with different horizontal thicknesses, current leakage occurring especially below a narrow semiconductor pattern causes a deterioration in the quality of the device.

However, according to some example embodiments, a thick epitaxial thin film is formed below a narrow semiconductor pattern, that is, the thicknesses of the epitaxial thin film are formed differently depending on the horizontal widths of the semiconductor patterns. Accordingly, the deterioration in electrical characteristics may be prevented or reduced in likelihood, and the electrical reliability of semiconductor devices may be improved.

FIGS. 2 to 9B are cross-sectional views showing a method of manufacturing an integrated circuit device 100, according to some example embodiments.

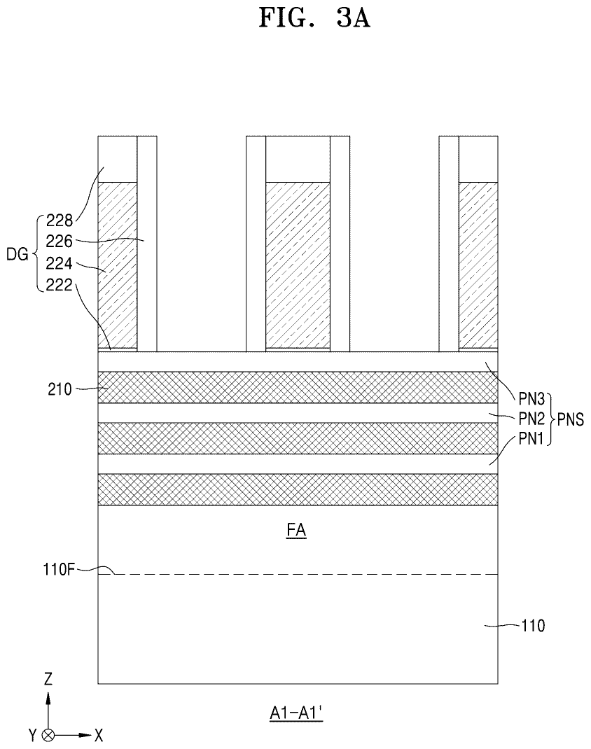

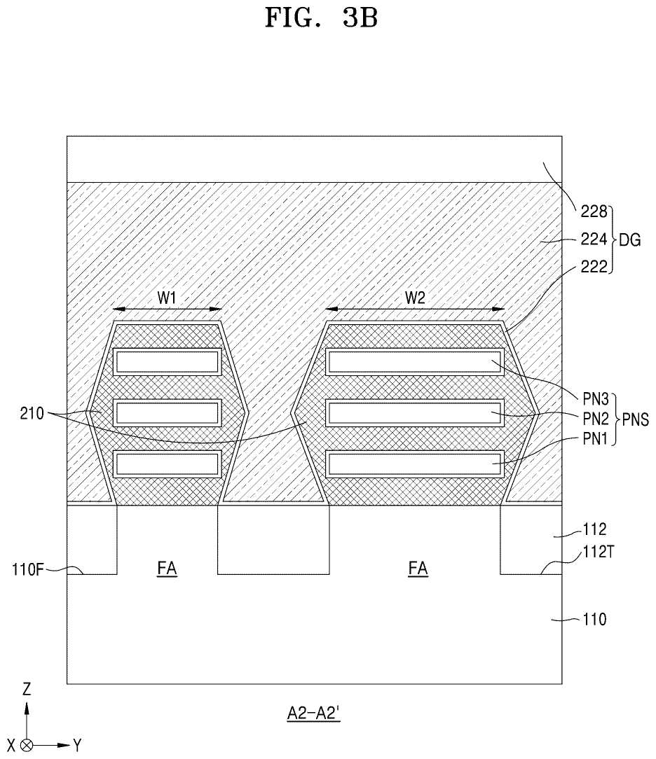

Specifically, FIGS. 2, 3A, 4, 5, 6, 7A, 8A, and 9A are cross-sectional views of the integrated circuit device 100 corresponding to the cross-section taken along line A1-A1′ of FIG. 1, and FIGS. 3B, 7B, 8B, and 9B are cross-sectional views of the integrated circuit device 100 corresponding to the cross-section taken along line A2-A2′ of FIG. 1.

Referring to FIG. 2, a sacrificial layer 210 and a channel semiconductor layer PNS may be alternately and sequentially formed on the upper surface of the substrate 110. The stack structure of the sacrificial layer 210 and the channel semiconductor layer PNS may be referred to as a channel semiconductor stack 210S.

In some example embodiments, the sacrificial layer 210 and the channel semiconductor layer PNS may be formed by an epitaxy process. In some example embodiments, the sacrificial layer 210 and the channel semiconductor layer PNS may include materials having an etch selectivity with respect to each other. For example, the sacrificial layer 210 and the channel semiconductor layer PNS may each include a single crystalline layer of a group IV semiconductor, a group IV-IV compound semiconductor, or a group III-V compound semiconductor, and the sacrificial layer 210 and the channel semiconductor layer PNS may include different materials. In some example embodiments, the sacrificial layer 210 may include SiGe, and the channel semiconductor layer PNS may include single crystalline silicon.

In some example embodiments, the epitaxy process may include vapor-phase epitaxy (VPE), a chemical vapor deposition (CVD) process, such as ultra-high vacuum (UHV) CVD, molecular beam epitaxy, or a combination thereof. During the epitaxy process, a liquid or gaseous precursor may be used as a precursor required to form the sacrificial layer 210 and the channel semiconductor layer PNS.

Referring to FIGS. 3A and 3B, subsequently, a hard mask pattern (not shown) extending to a certain length in the first horizontal direction (the X direction) is formed on the uppermost channel semiconductor layer PNS. Then, the sacrificial layer 210, the channel semiconductor layer PNS, and the substrate 110 may be etched using the hard mask pattern as an etch mask. The stack structure of the channel semiconductor layer PNS and the sacrificial layer 210 may have a line-type pattern shape extending in the first horizontal direction (the X direction), and the device isolation trench 112T may be formed in the substrate 110 between stack line patterns of the channel semiconductor layer PNS and the sacrificial layer 210.

For example, the channel semiconductor layer PNS may include a first channel semiconductor layer PN1, a second channel semiconductor layer PN2, and a third channel semiconductor layer PN3, which are spaced apart from each other in the vertical direction (the Z direction) above the first surface 110F of the substrate 110. The sacrificial layer 210 may be located between the upper surface of the substrate 110 and the first channel semiconductor layer PN1, between the first channel semiconductor layer PN1 and the second channel semiconductor layer PN2, and between the second channel semiconductor layer PN2 and the third channel semiconductor layer PN3.

The channel semiconductor layers PNS may extend in the first horizontal direction (the X direction) and be spaced apart from each other in the second horizontal direction (the Y direction). Referring to FIG. 3B, the widths of the channel semiconductor layers PNS in the second horizontal direction (the Y direction) may be different from each other. For example, the width, in the second horizontal direction (the Y direction), of the channel semiconductor layer PNS on the left may be a first width W1. Also, the width, in the second horizontal direction (the Y direction), of the channel semiconductor layer PNS on the right may be a second width W2. In some example embodiments, the second width W2 may be greater than the first width W1. For example, the second width W2 may be greater than or equal to 30 nm (e.g., from about 30 nm to about 100 nm), and the first width W1 may be less than 30 nm (e.g., from about 30 nm to about 5 nm). In some example embodiments, the first width W1 may be approximately 10 nm and the second width W2 may be approximately 30 nm, but the inventive concepts are not limited thereto.

Subsequently, the inside of the device isolation trench 112T is filled with an insulating material, and the upper portion of the insulating material is flattened. Accordingly, the device isolation film 112 filling the device isolation trench 112T may be formed. The fin-type active regions FA may be defined in the substrate 110 by the device isolation film 112.

Subsequently, a sacrificial gate structure DG may be formed on the device isolation film 112 and the stack line patterns of the channel semiconductor layer PNS and the sacrificial layer 210. Each of the sacrificial gate structures DG may include a sacrificial insulating layer pattern 222, a sacrificial gate line 224, a sacrificial gate spacer 226, and a sacrificial gate capping layer 228.

The sacrificial insulating layer pattern 222 may extend in the second horizontal direction (the Y direction), and may be conformally formed on the upper surface and sidewalls of the stack line patterns of the channel semiconductor layer PNS and the sacrificial layer 210 and on the upper surface of the device isolation film 112. In some example embodiments, the sacrificial insulating layer pattern 222 may include a material having an etch selectivity with the sacrificial gate line 224 and may include, for example, at least one film selected from a group consisting of thermal oxide, silicon oxide, and/or silicon nitride.

The sacrificial gate line 224 may have a relatively large height on the sacrificial insulating layer pattern 222 to cover the stack line patterns of the channel semiconductor layer PNS and the sacrificial layer 210. The upper surface of the sacrificial gate line 224 may have a flat level. In some example embodiments, the sacrificial gate line 224 may include polysilicon, but the example embodiment is not limited thereto.

The sacrificial gate spacer 226 may be disposed on the sidewall of the sacrificial gate line 224. In some example embodiments, the sacrificial gate spacer 226 may include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N₂), or a combination thereof.

The sacrificial gate capping layer 228 may be disposed on the upper surface of the sacrificial gate line 224, and both sidewalls of the sacrificial gate capping layer 228 may be covered by the sacrificial gate spacer 226. In some example embodiments, the sacrificial gate capping layer 228 may include a silicon nitride film.

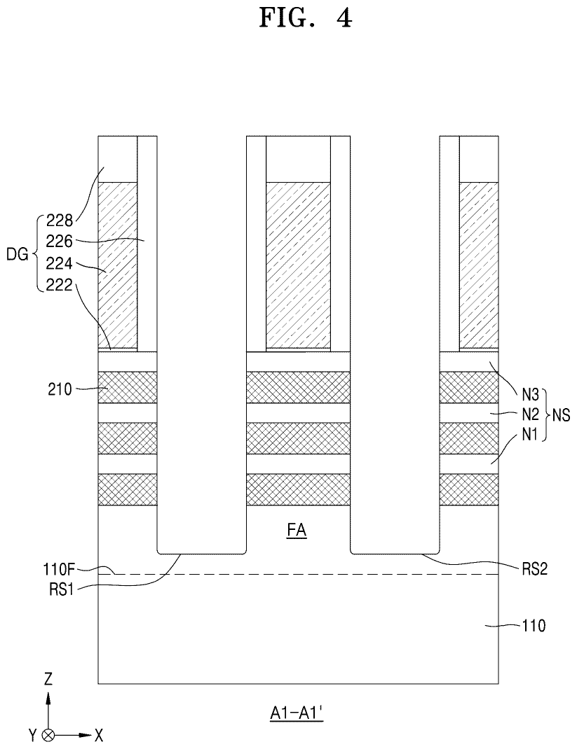

Referring to FIG. 4, the stack line patterns of the channel semiconductor layer PNS and the sacrificial layer 210 and a portion of the substrate 110 may be etched on both sides of the sacrificial gate structure DG, and thus, the recesses RS1 and RS2 may be formed on both sides of the sacrificial gate structure DG. As the recesses RS1 and RS2 are formed, the channel semiconductor layer PNS may be separated into the plurality of semiconductor patterns NS. For example, as the recesses RS are formed, a structure, in which a plurality of sacrificial layers 210 and a plurality of semiconductor patterns NS are alternately arranged, may be formed on the fin-type active region FA.

The recesses RS1 and RS2 may be referred to as the first recess RS1 and the second recess RS2. The first recess RS1 and the second recess RS2 may be formed to the same depth and width through the same process.

In some example embodiments, as illustrated in FIG. 4, the recesses RS1 and RS2 may include sidewalls that extend continuously and are aligned with both sidewalls of the sacrificial gate structures DG, for example, both sidewalls of the sacrificial gate spacers 226. For example, the sidewalls of each of the plurality of semiconductor patterns NS, which are exposed by the recesses RS1 and RS2, may be aligned with the sidewalls of the sacrificial gate spacer 226 and form a continuous sidewall profile.

FIG. 4 illustrates some example embodiments in which the recesses RS1 and RS2 have substantially the same width over the entire heights thereof and the recesses RS1 and RS2 have vertical sidewall profiles. Accordingly, the plurality of semiconductor patterns NS have substantially the same width in the first horizontal direction (the X direction). However, in some example embodiments, the widths of lower portions of the recesses RS1 and RS2 may be less than the widths of upper portions of the recesses RS1 and RS2, and the recesses RS1 and RS2 may have inclined sidewall profiles. Accordingly, at least one of the plurality of semiconductor patterns NS (e.g., the lowermost semiconductor pattern NS or the first nanosheet N1) may have a greater width than the other semiconductor patterns NS.

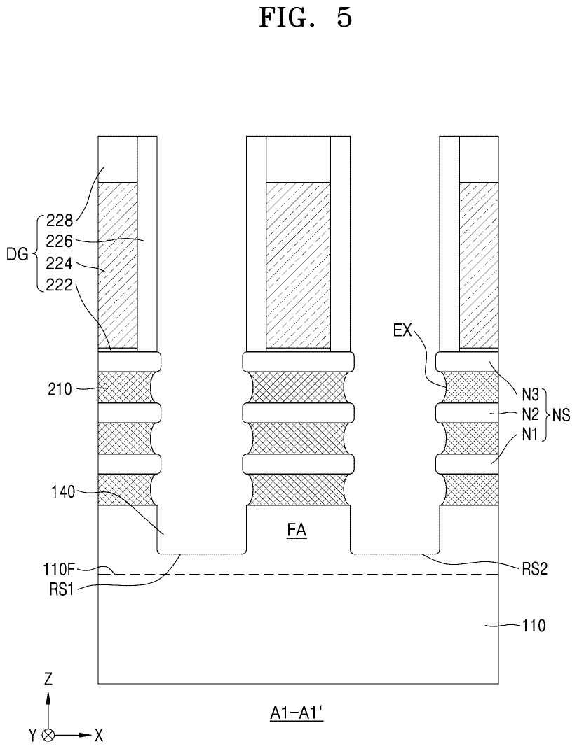

Referring to FIG. 5, the sacrificial layers 210 exposed on the sidewall of the recesses RS1 and RS2 may be partially removed to form indents EX. For example, the sacrificial layer 210 may be partially removed by a wet etching process or a dry etching process that uses etch conditions having selective etch characteristics with respect to the sacrificial layer 210. In some example embodiments, each of the indents EX may represent a sidewall of the sacrificial layer 210 that is recessed inwardly relative to the sidewalls of the plurality of semiconductor patterns NS, or may represent a space provided by a sidewall of the sacrificial layer 210 that is recessed inwardly between the semiconductor patterns NS adjacent to each other in the vertical direction (the Z direction). Alternatively, in some example embodiments, the seed area of silicon in the semiconductor pattern NS may increase, and thus, the semiconductor pattern NS may grow further in the first horizontal direction (the X direction) than the sacrificial layer 210. As a result, indents EX may be formed.

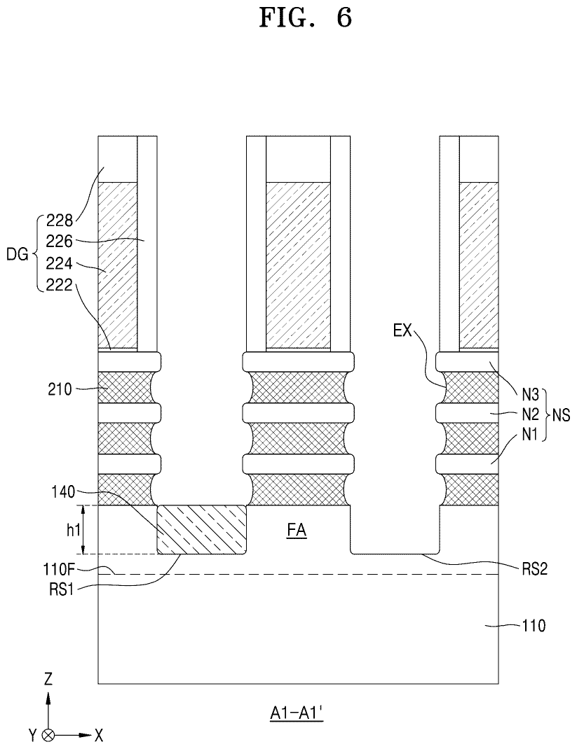

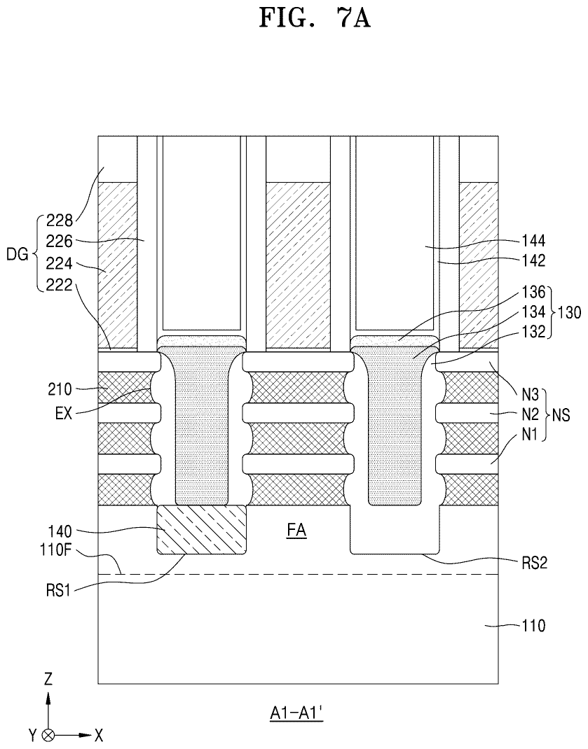

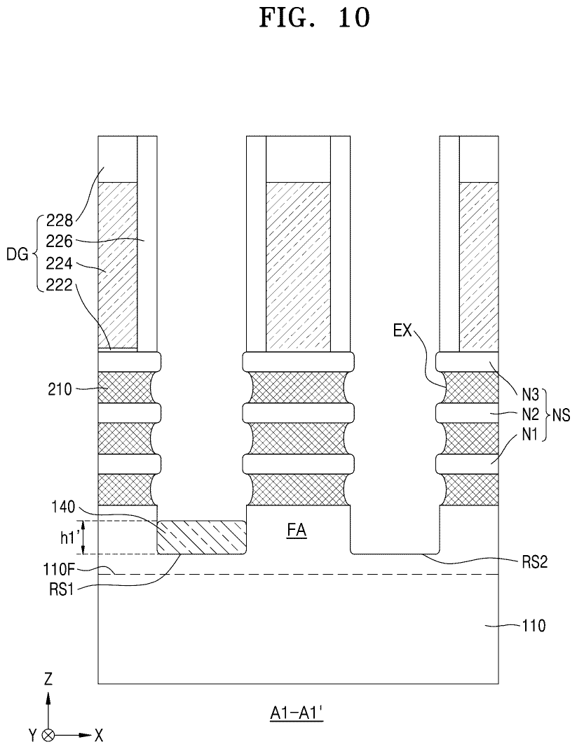

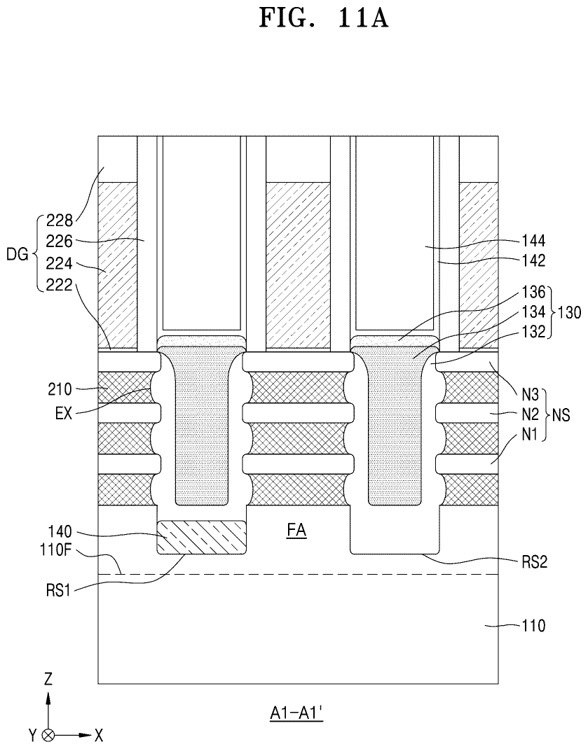

Referring to FIG. 6, the lower thin film 140 may be formed in the first recess RS1. The lower thin film 140 may be formed by an epitaxy process. The lower thin film 140 may have a first height h1 in the vertical direction (the Z direction). For example, the first height h1 may be greater than or equal to 8 nm, but the inventive concepts are not limited thereto. FIG. 6 illustrates that the upper surface of the lower thin film 140 is at the same vertical level as the upper surface of the fin-type active region FA. However, this is only one example, and the inventive concepts are not limited thereto. In some example embodiments, the upper surface of the lower thin film 140 may be at a lower vertical level than the upper surface of the fin-type active region FA (see FIG. 10).

The lower thin film 140 may include undoped Si, SiB, SiN, or a combination thereof. Although FIG. 6 illustrates that the lower thin film 140 is formed as a single layer, the lower thin film 140 may be formed as a double layer or a multi layer.

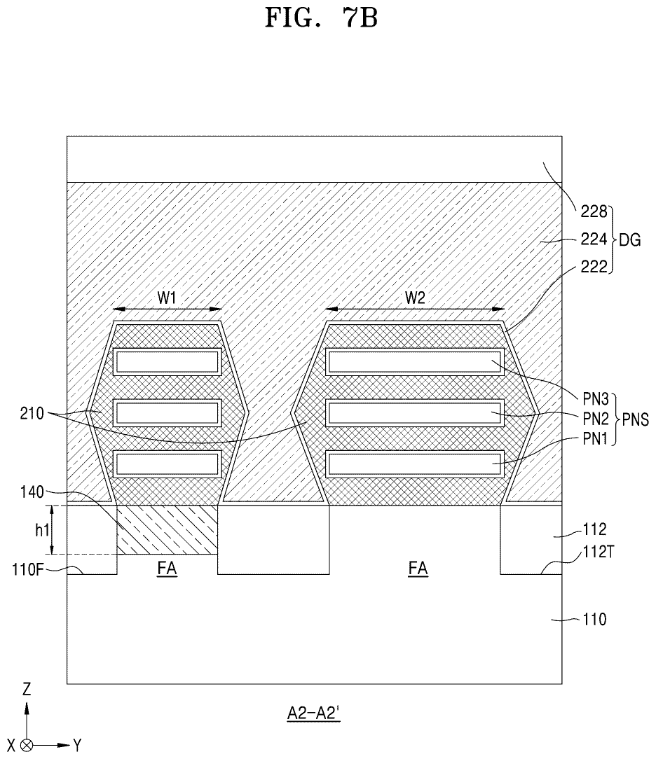

Referring to FIGS. 7A and 7B, the source/drain regions 130 may be formed inside the recesses RS1 and RS2. For example, the source/drain region 130 may be formed on the lower thin film 140 in the first recess RS1 by epitaxially growing semiconductor materials from surfaces of the plurality of semiconductor patterns NS, the sacrificial layer 210, and the substrate 110 which are exposed to the inner walls of the first recess RS1. The source/drain region 130 may be formed in the second recess RS2 by epitaxially growing semiconductor materials from surfaces of the plurality of semiconductor patterns NS, the sacrificial layer 210, and the substrate 110 which are exposed to the inner walls of the second recess RS2. The source/drain region 130 may be formed by sequentially forming the buffer layer 132, the main semiconductor layer 134, and the capping layer 136 on the inner walls of each of the recesses RS1 and RS2. For example, in some example embodiments, the main semiconductor layer 134 may be in contact with a top surface of the lower thin film 140. In some example embodiments, in the second recess RS2 the buffer layer 132 may contact side walls of the substrate 110 defining the second recess RS2. In some example embodiments, the first recess RS1 may include a lower thin film 140 and the second recess RS2 may omit a lower thin film. However, the example embodiments are not so limited thereto as described below, both a first recess RS1 and a second recess RS2 may include a lower thin film 140.

In some example embodiments, the buffer layer 132 may be formed on the inner wall of the recesses RS1 and RS2 to a thickness that does not completely fill the interior of the recesses RS1 and RS2. The buffer layer 132 may be in contact with the surfaces of the plurality of semiconductor patterns NS, the sacrificial layer 210, and the substrate 110 which are exposed to the inner walls of the recesses RS1 and RS2.

In some example embodiments, the buffer layer 132 may be formed using a semiconductor material that includes a first element as a dopant. In some example embodiments, the first element may include at least one of fluorine, oxygen, argon, and/or nitrogen.

For example, the buffer layer 132 may be epitaxially grown by using, as seed layers, the sidewall of the semiconductor pattern NS exposed on the inner walls of the recesses RS1 and RS2, the sidewall of the sacrificial layer 210 (e.g., the exposed surface of the indent EX) exposed on the inner walls of the recesses RS1 and RS2, and the upper surface of the substrate 110 exposed on the bottom of the recesses RS1 and RS2 (in the case of the second recess RS2) or the upper surface of the lower thin film 140 (in the case of the first recess RS1).

In some example embodiments, the main semiconductor layer 134 may have a relatively large thickness on the buffer layer 132 to fill the interior of the recesses RS1 and RS2. In some example embodiments, the upper surface of the main semiconductor layer 134 may be at a higher level than the uppermost semiconductor pattern NS.

In some example embodiments, the main semiconductor layer 134 may be formed by using at least one semiconductor material of SiGe, SiP, and SiGeB. The main semiconductor layer 134 may be epitaxially grown by using the inner wall of the buffer layer 132 as a seed layer.

In some example embodiments, the capping layer 136 may include a semiconductor material. For example, the capping layer 136 may include doped or undoped silicon. The capping layer 136 may be formed to a relatively small thickness that covers the upper surface and sidewalls of the main semiconductor layer 134.

Subsequently, the passivation layer 142 and the inter-gate insulating layer 144 may be formed to cover the sacrificial gate structure DG and the source/drain region 130. The passivation layer 142 may have a small thickness, and the inter-gate insulating layer 144 may have a relatively large height to fill the space between two adjacent sacrificial gate structures DG. The upper surface of the inter-gate insulating layer 144 may be on the same plane as the upper surface of the sacrificial gate structure DG.

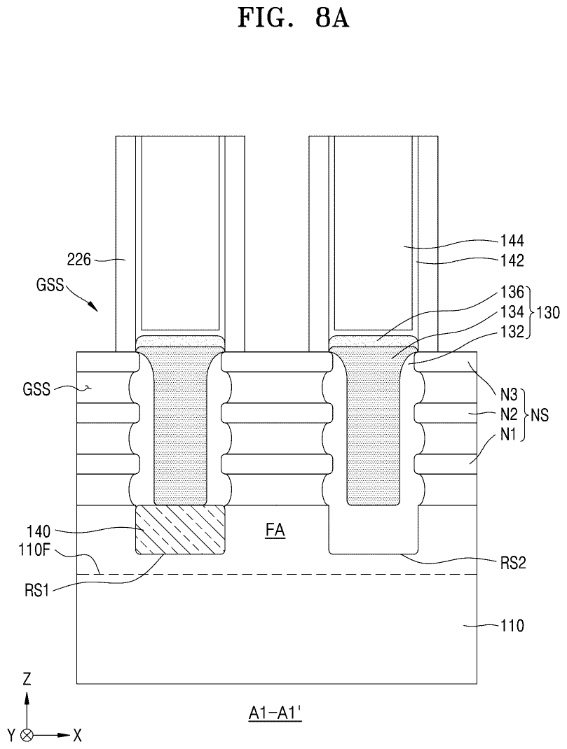

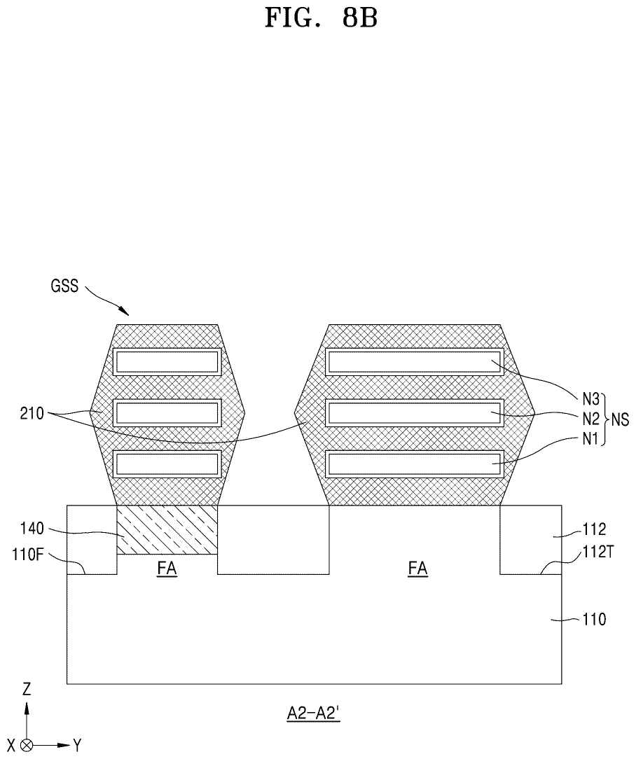

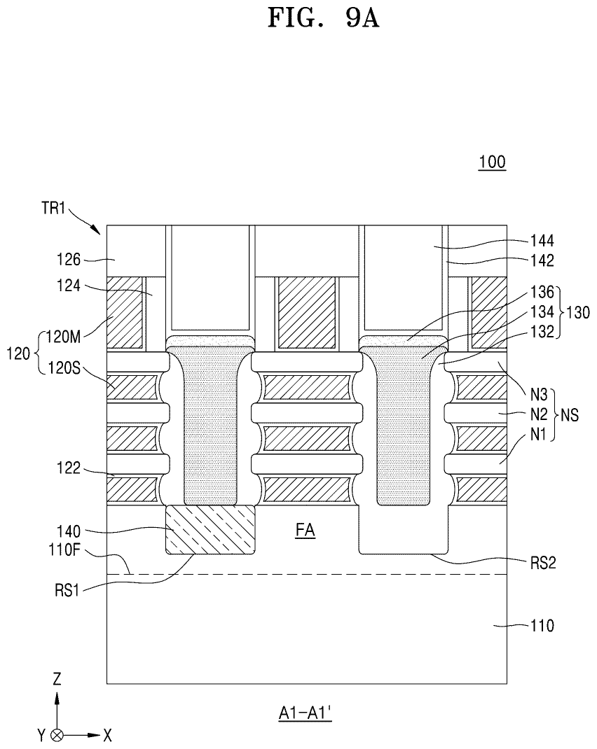

Referring to FIGS. 8A and 8B, the sacrificial gate capping layer 228 may be removed by planarizing the upper surfaces of the sacrificial gate structure DG and the inter-gate insulating layer 144. The upper surface of the sacrificial gate line 224 may be exposed by the planarization process.

Subsequently, the sacrificial gate line 224 and the sacrificial insulating layer pattern 222 may be removed to form a gate space GSS. For example, the gate space GSS may be defined between two adjacent sacrificial gate spacers 226, and the upper surfaces of the sidewalls of the plurality of semiconductor patterns NS and the sidewalls of the sacrificial layer 210 may be exposed to the gate space GSS.

Subsequently, the plurality of sacrificial layers 210 remaining on the fin-type active region FA may be removed through the gate space GSS, thereby partially exposing the plurality of semiconductor patterns NS, the upper surface of the fin-type active region FA, and the upper surface of the lower thin film 140. The process of removing the plurality of sacrificial layers 210 may include a wet etching process that utilizes the difference in etch selectivities between the sacrificial layers 210 and the plurality of semiconductor patterns NS.

Referring to FIGS. 9A and 9B, the gate insulating layer 122 may be formed on the surfaces exposed to the gate space GSS. Subsequently, the gate line 120 may be formed on the gate insulating layer 122 to fill the gate space GSS. For example, a work function conductive layer (not shown) is formed conformally on the inner wall of the gate space GSS, and then a buried conductive layer (not shown) is formed on the work function conductive layer. As a result, the gate space GSS may be filled. The upper portion of the buried conductive layer may then be planarized to expose the upper surface of the inter-gate insulating layer 144, thereby forming the gate line 120.

In some example embodiments, the work-function control layer may be formed by using Al, Cu, Ti, Ta, W, Mo, TaN, NiSi, CoSi, TiN, WN, TiAl, TiAlC, TiAlN, TaCN, TaC, TaSiN, or a combination thereof. The buried conductive layer may be formed by using Al, Cu, Ti, Ta, W, Mo, TaN, NiSi, CoSi, TiN, WN, TiAl, TiAlC, TiAlN, TaCN, TaC, TaSiN, or a combination thereof.

Subsequently, the upper portions of the gate line 120, the gate insulating layer 122, and the sacrificial gate spacer 226 may be partially removed, and the gate capping layer 126 may be formed on the upper portion of the gate space GSS. Here, the remaining portion of the sacrificial gate spacer 226 may be referred to as the outer insulating spacer 124.

By the processes described above, the integrated circuit device 100 may be formed.

In order to minimize or reduce current leakage from the semiconductor pattern NS having a small width in the second horizontal direction (the Y direction) to below the source/drain region 130, the lower thin film 140 having a certain thickness is selectively formed below the source/drain region 130 corresponding to the narrow semiconductor pattern NS. Accordingly, the integrated circuit device 100 may have improved electrical reliability.

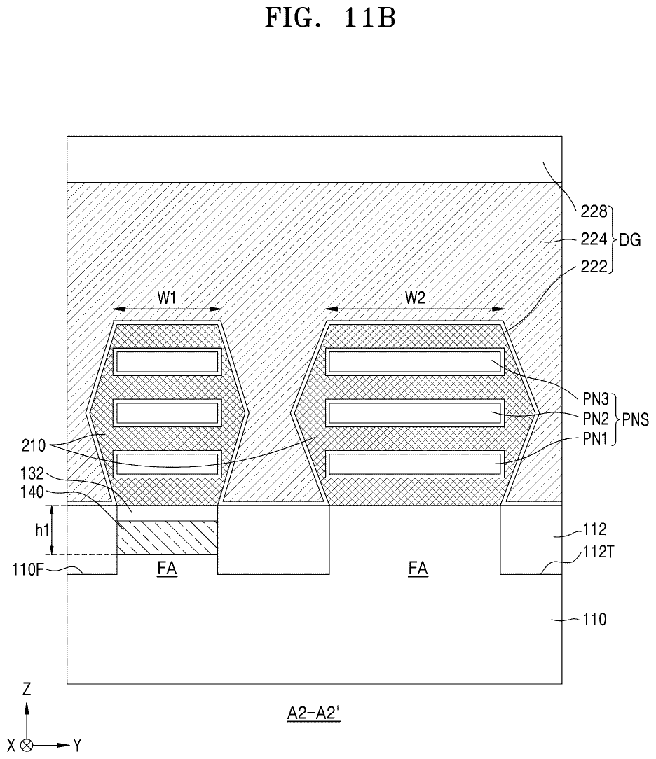

FIGS. 10 to 13B are cross-sectional views showing a method of manufacturing an integrated circuit device 100a, according to some example embodiments. Specifically, FIGS. 10, 11A, 12A, and 13A are cross-sectional views of the integrated circuit device 100a corresponding to the cross-section taken along line A1-A1′ of FIG. 1, and FIGS. 11B, 12B, and 13B are cross-sectional views of the integrated circuit device 100a corresponding to the cross-section taken along line A2-A2′ of FIG. 1.

It will be understood that the integrated circuit device 100a of FIGS. 10 to 13B is not mutually exclusive with the integrated circuit device 100 described with reference to FIGS. 1 to 9B, and elements having the same reference numerals represent the same components. Hereinafter, repeated descriptions of the same components are omitted, and the differences from the integrated circuit device 100 of FIGS. 1 to 9B are mainly described.

Some of the manufacturing processes of the integrated circuit device 100a of FIGS. 10 to 13B may be performed in the same manner as the manufacturing process of the integrated circuit device 100 described with reference to FIGS. 2, 3A, 3B, 4, and 5.

Referring to FIG. 10, a lower thin film 140 may partially fill the first recess RS1 in the result of FIG. 5. The lower thin film 140 may be formed by an epitaxy process. The lower thin film 140 may have a first height h1′ in the vertical direction (the Z direction). The upper surface of the lower thin film 140 may be at a lower vertical level than the upper surface of the fin-type active region FA.

The lower thin film 140 may include undoped Si, SiB, SiN, or a combination thereof. Although FIG. 10 illustrates that the lower thin film 140 is formed as a single layer, the lower thin film 140 may be formed as a double layer or a multi layer.

Referring to FIGS. 11A and 11B, the source/drain regions 130 may be formed inside the recesses RS1 and RS2. For example, the source/drain region 130 may be formed on the lower thin film 140 in the first recess RS1 by epitaxially growing semiconductor materials from surfaces of the plurality of semiconductor patterns NS, the sacrificial layer 210, and the substrate 110 which are exposed to the inner walls of the first recess RS1. The source/drain region 130 may be formed in the second recess RS2 by epitaxially growing semiconductor materials from surfaces of the plurality of semiconductor patterns NS, the sacrificial layer 210, and the substrate 110 which are exposed to the inner walls of the second recess RS2. In some example embodiments, the buffer layer 132 in the first recess RS1 may extend between the main semiconductor layer 134 and the lower thin film 140. In some example embodiments, the buffer layer 132 may at least partially cover side walls of the substrate 110 in the first recess RS1. In some example embodiments, the first buffer layer 132 may cover the exposed inner walls of the second recess RS2 defined by the substrate 110.

The source/drain region 130 may be formed by sequentially forming the buffer layer 132, the main semiconductor layer 134, and the capping layer 136 on the inner walls of each of the recesses RS1 and RS2. Subsequently, the passivation layer 142 and the inter-gate insulating layer 144 may be formed to cover the sacrificial gate structure DG and the source/drain region 130.

The method of forming the buffer layer 132, the main semiconductor layer 134, the capping layer 136, the passivation layer 142, and the inter-gate insulating layer 144 of FIGS. 11A and 11B and the constituent materials of each layer may be the same as the method of forming the buffer layer 132, the main semiconductor layer 134, the capping layer 136, the passivation layer 142, and the inter-gate insulating layer 144 of the integrated circuit device 100 and the constituent materials of each layer.

Since the upper surface of the lower thin film 140 is at a lower vertical level than the upper surface of the fin-type active region FA in cross-section A1-A1′ of FIG. 11A, the buffer layer 132 may be illustrated as being exposed on the device isolation film 112 in cross-section A2-A2′ of FIG. 11B. The buffer layer 132 may be shown between the lower thin film 140 and the lowermost sacrificial layer 210 in cross-section A2-A2′ of FIG. 11B.

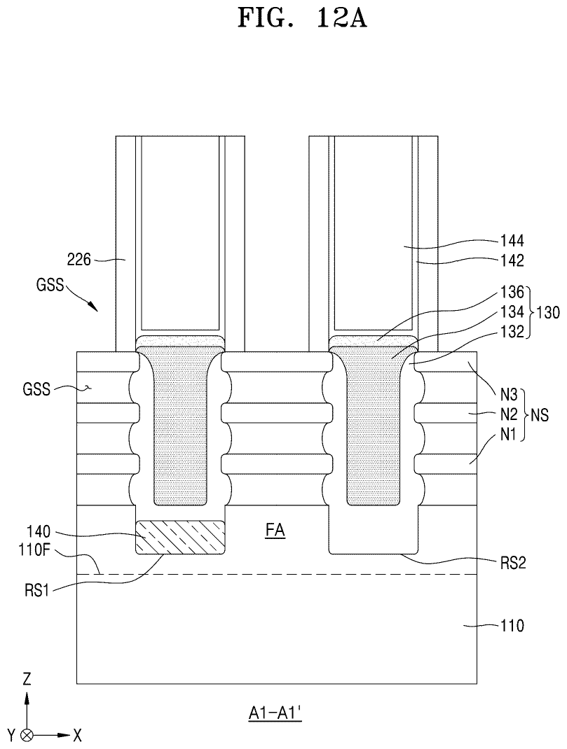

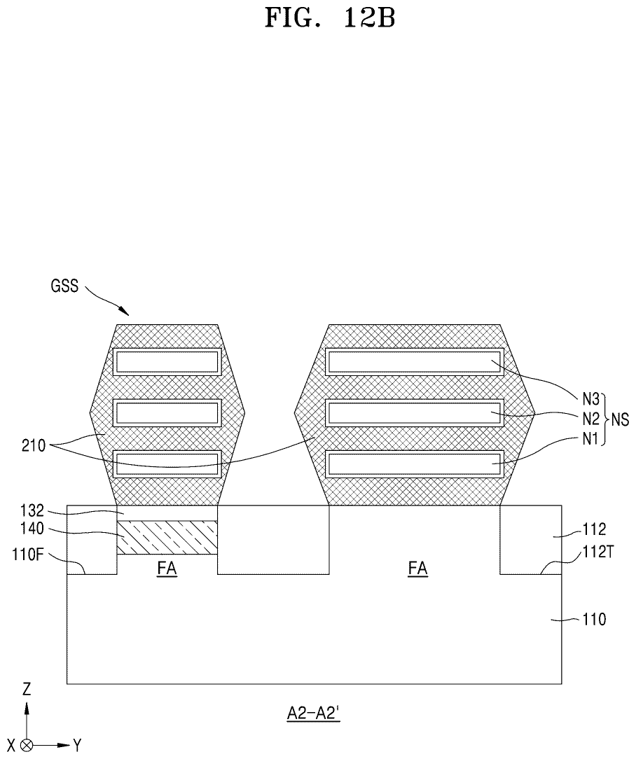

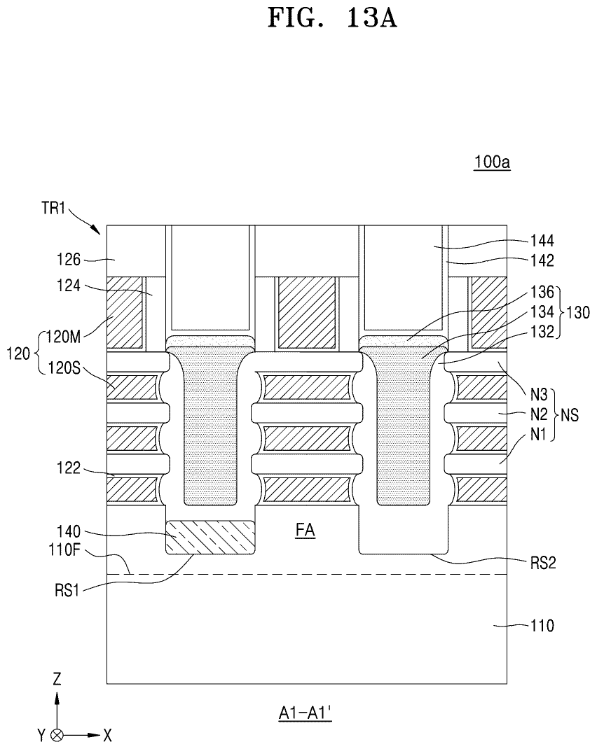

Referring to FIGS. 12A and 12B, the sacrificial gate capping layer 228 may be removed by planarizing the upper surfaces of the sacrificial gate structure DG and the inter-gate insulating layer 144. The upper surface of the sacrificial gate line 224 may be exposed by the planarization process.

Subsequently, the sacrificial gate line 224 and the sacrificial insulating layer pattern 222 are removed to form the gate space GSS, and the plurality of sacrificial layers 210 remaining on the fin-type active region FA are removed through the gate space GSS. Accordingly, the plurality of semiconductor patterns NS, the upper surface of the fin-type active region FA, and the upper surface of the buffer layer 132 may be partially exposed. During the above process, the lower thin film 140 may not be exposed by the buffer layer 132.

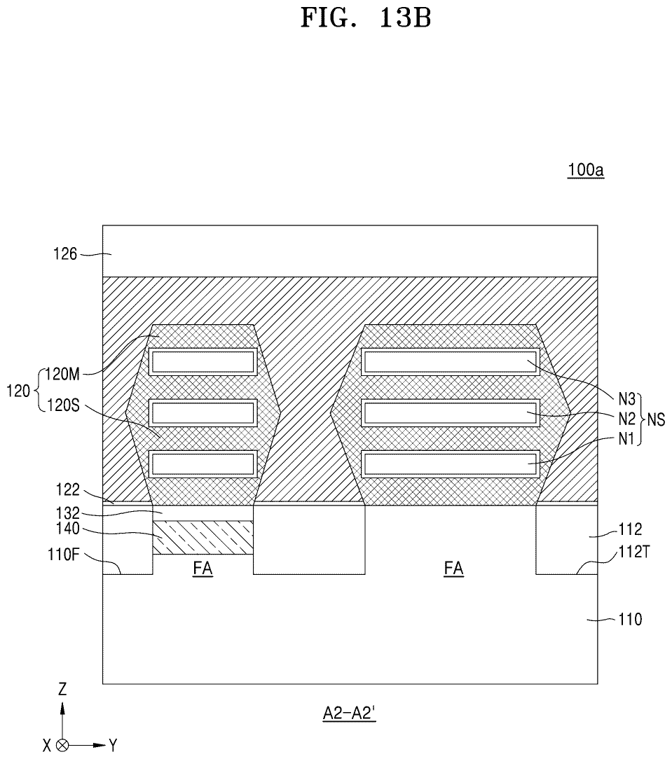

Referring to FIGS. 13A and 13B, the gate insulating layer 122 may be formed on the surfaces exposed to the gate space GSS, and then the gate line 120 filling the gate space GSS may be formed on the gate insulating layer 122. Subsequently, the upper portions of the gate line 120, the gate insulating layer 122, and the sacrificial gate spacer 226 may be partially removed, and the gate capping layer 126 may be formed on the upper portion of the gate space GSS. Here, the remaining portion of the sacrificial gate spacer 226 may be referred to as the outer insulating spacer 124.

By the processes described above, the integrated circuit device 100a may be formed.

The integrated circuit device 100a may have almost the same characteristics and effects as the integrated circuit device 100 except that the upper surface of the lower thin film 140 formed in the first recess RS1 is at a lower vertical level than the upper surface of the fin-type active region FA.

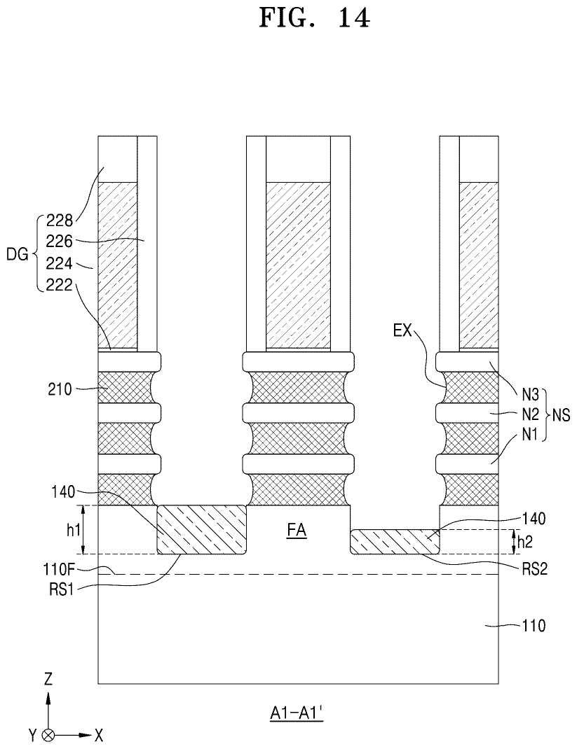

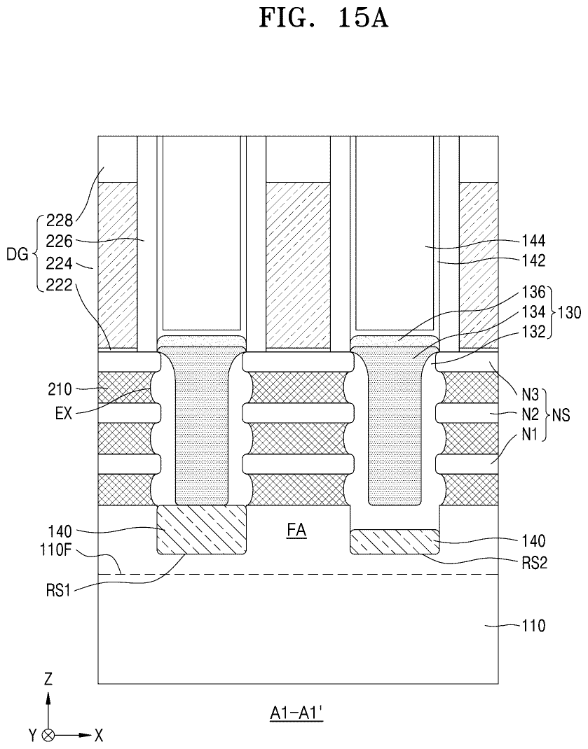

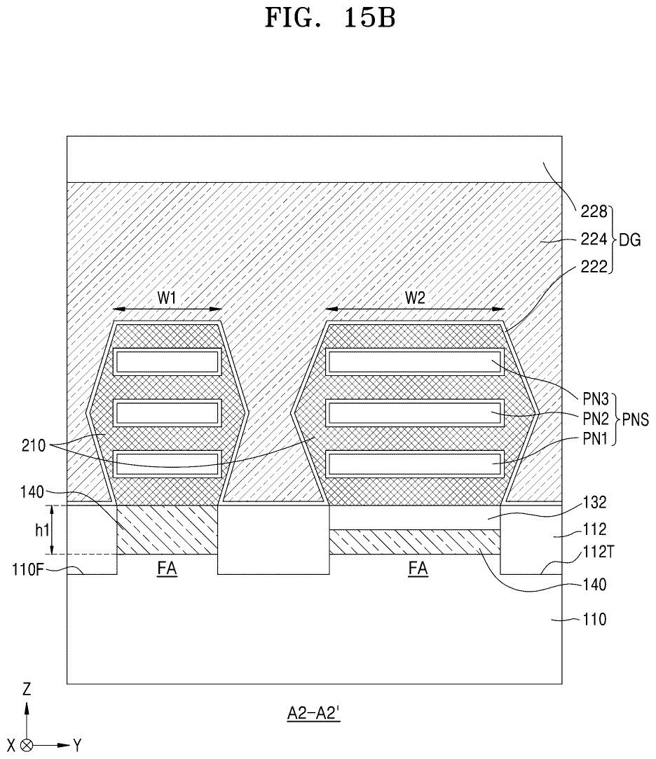

FIGS. 14 to 17B are cross-sectional views showing a method of manufacturing an integrated circuit device 100b, according to some example embodiments. Specifically, FIGS. 14, 15A, 16A, and 17A are cross-sectional views of the integrated circuit device 100b corresponding to the cross-section taken along line A1-A1′ of FIG. 1, and FIGS. 15B, 16B, and 17B are cross-sectional views of the integrated circuit device 100b corresponding to the cross-section taken along line A2-A2′ of FIG. 1.

It will be understood that the integrated circuit device 100b of FIGS. 14 to 17B is not mutually exclusive with the integrated circuit device 100 described with reference to FIGS. 1 to 9B, and elements having the same reference numerals represent the same components. Hereinafter, repeated descriptions of the same components are omitted, and the differences from the integrated circuit device 100 of FIGS. 1 to 9B are mainly described.

Some of the manufacturing processes of the integrated circuit device 100b of FIGS. 14 to 17B may be performed in the same manner as the manufacturing process of the integrated circuit device 100 described with reference to FIGS. 2, 3A, 3B, 4, and 5.

Referring to FIG. 14, a lower thin film 140 may partially fill each of the first recess RS1 and the second recess RS2 in the result of FIG. 5. The lower thin film 140 may be formed by an epitaxy process. The lower thin film 140 formed in the first recess RS1 may have a first height h1 in the vertical direction (the Z direction), and the lower thin film 140 formed in the second recess RS2 may have a second height h2 in the vertical direction (the Z direction).

In some example embodiments, the first height h1 may be greater than the second height h2. For example, the first height h1 may be greater than or equal to 8 nm, and the second height h2 may be less than 8 nm. However, the inventive concepts are not limited thereto.

In order to minimize or reduce current leakage from the semiconductor patterns NS having different widths in the second horizontal direction (the Y direction) to below the source/drain regions 130, the lower thin film 140 disposed below the source/drain region 130 adjacent to a narrow semiconductor pattern NS is formed to a large thickness. Accordingly, the integrated circuit device 100b may have improved electrical reliability. Therefore, the first height h1 may be greater than the second height h2.

In some example embodiments, the lower thin film 140 formed in the first recess RS1 and the lower thin film 140 formed in the second recess RS2 may be formed simultaneously, or any one of these lower thin films 140 may be formed first. In the case in which the lower thin films 140 are formed separately and sequentially, while the lower thin film 140 is formed first in one recess, the formation of an undesired lower thin film may be suppressed in the other recess, for example, by a mask or the like.

FIG. 14 illustrates that the upper surface of the lower thin film 140 formed in the first recess RS1 is coplanar with the upper surface of the fin-type active region FA, but this is only one example. As long as the relative relationship between the first height h1 and the second height h2 is satisfied, the upper surface of the lower thin film 140 may be at a lower vertical level than the upper surface of the fin-type active region FA as in the integrated circuit device 100a described above.

The lower thin film 140 may include undoped Si, SiB, SiN, or a combination thereof. Although FIG. 14 illustrates that the lower thin film 140 is formed as a single layer, the lower thin film 140 may be formed as a double layer or a multi layer.

Referring to FIGS. 15A and 15B, the source/drain regions 130 may be formed inside the recesses RS1 and RS2. For example, the source/drain regions 130 may be formed on the lower thin films 140 by epitaxially growing semiconductor materials from surfaces of the plurality of semiconductor patterns NS, the sacrificial layer 210, and the substrate 110 which are exposed to the inner walls of the recesses RS1 and RS2.

The source/drain region 130 may be formed by sequentially forming the buffer layer 132, the main semiconductor layer 134, and the capping layer 136 on the inner walls of each of the recesses RS1 and RS2. Subsequently, the passivation layer 142 and the inter-gate insulating layer 144 may be formed to cover the sacrificial gate structure DG and the source/drain region 130.

The method of forming the buffer layer 132, the main semiconductor layer 134, the capping layer 136, the passivation layer 142, and the inter-gate insulating layer 144 of FIGS. 15A and 15B and the constituent materials of each layer may be the same as the method of forming the buffer layer 132, the main semiconductor layer 134, the capping layer 136, the passivation layer 142, and the inter-gate insulating layer 144 of each of the integrated circuit devices 100 and 100a and the constituent materials of each layer.

Since the upper surface of the lower thin film 140 formed on the right is at a lower vertical level than the upper surface of the fin-type active region FA in cross-section A1-A1′ of FIG. 15A, the buffer layer 132 may be illustrated as being exposed on the device isolation film 112 in cross-section A2-A2′ of FIG. 15B. The buffer layer 132 may be shown between the lower thin film 140 and the lowermost sacrificial layer 210 in cross-section A2-A2′ of FIG. 15B. Although not shown separately, when the upper surface of the lower thin film 140 formed on the left is also at a lower vertical level than the upper surface of the fin-type active region FA, the buffer layer 132 may be exposed on the lower thin films 140 on both sides in cross-section the A2-A2′ of FIG. 15B.

Since the first recess RS1 and the second recess RS2 are formed to the same depth (see FIG. 4), the lower thin films 140 formed on the left and right sides in FIG. 15B may have the same vertical level on the lower surfaces thereof.

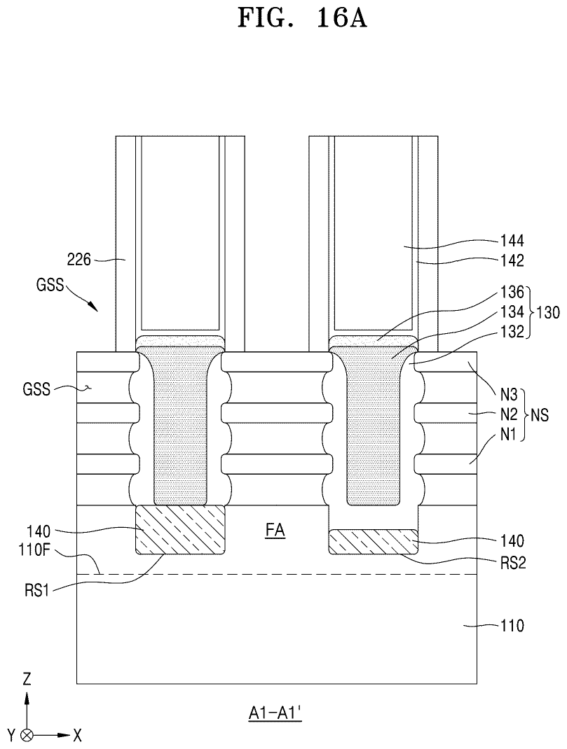

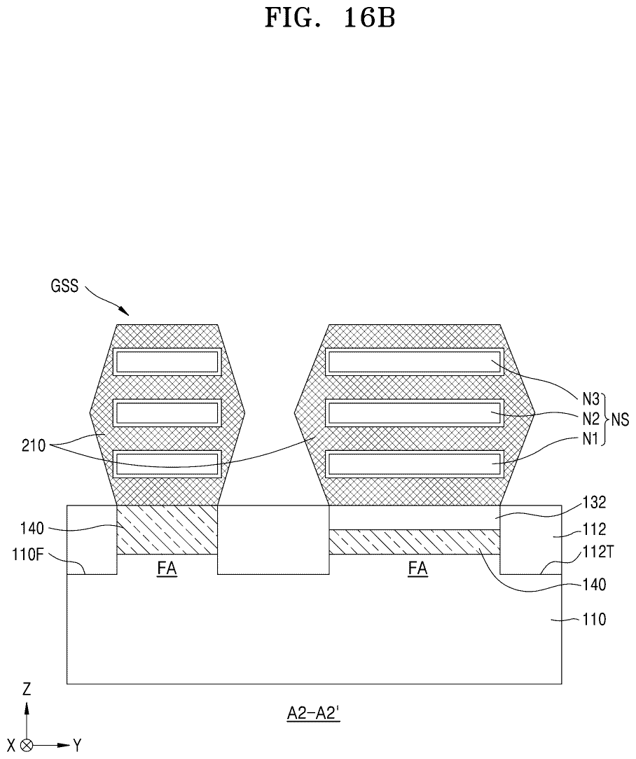

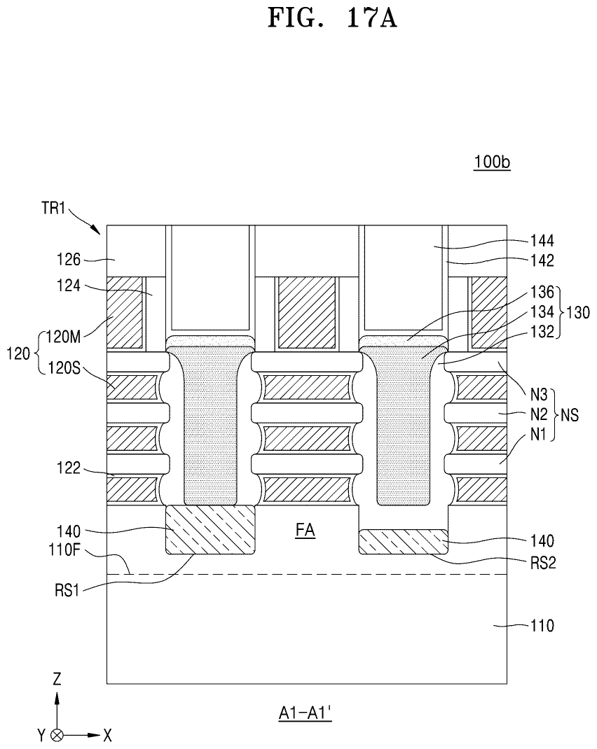

Referring to FIGS. 16A and 16B, the sacrificial gate capping layer 228 may be removed by planarizing the upper surfaces of the sacrificial gate structure DG and the inter-gate insulating layer 144. The upper surface of the sacrificial gate line 224 may be exposed by the planarization process.

Subsequently, the sacrificial gate line 224 and the sacrificial insulating layer pattern 222 are removed to form the gate space GSS, and the plurality of sacrificial layers 210 remaining on the fin-type active region FA are removed through the gate space GSS. Accordingly, the plurality of semiconductor patterns NS and the upper surface of the buffer layer 132 may be partially exposed. During the above process, the lower thin film 140 may not be exposed by the buffer layer 132.

Referring to FIGS. 17A and 17B, the gate insulating layer 122 may be formed on the surfaces exposed to the gate space GSS, and then the gate line 120 filling the gate space GSS may be formed on the gate insulating layer 122. Subsequently, the upper portions of the gate line 120, the gate insulating layer 122, and the sacrificial gate spacer 226 may be partially removed, and the gate capping layer 126 may be formed on the upper portion of the gate space GSS. Here, the remaining portion of the sacrificial gate spacer 226 may be referred to as the outer insulating spacer 124.

By the processes described above, the integrated circuit device 100b may be formed.

The integrated circuit device 100b may have almost the same characteristics and effects as the integrated circuit device 100 except that the thicknesses of the lower thin films 140 respectively formed in the first recess RS1 and the second recess RS2 in the vertical direction (the Z direction) are different from each other.

While the inventive concepts have been particularly shown and described with reference to some example embodiments thereof, it will be understood that various changes in form and details may be made therein without departing from the spirit and scope of the following claims.

What is claimed is:

1. An integrated circuit device comprising:
a fin-type active region protruding from a substrate and extending in a first direction;
a first semiconductor pattern and a second semiconductor pattern spaced apart from each other in the first direction and a second direction, the second direction intersecting the first direction, the first semiconductor pattern and the second semiconductor pattern are above the fin-type active region;
a gate line extending in the second direction, the gate line above the fin-type active region and surrounding the first and second semiconductor patterns;
a first source/drain region and a second source/drain region adjacent to the gate line above the fin-type active region, the first source/drain region being connected to the first semiconductor pattern, the second source/drain region being connected to the second semiconductor pattern; and
a lower thin film on the fin-type active region and below the first source/drain region in a third direction intersecting the first direction and the second direction,
wherein the second semiconductor pattern has a greater width than the first semiconductor pattern in the second direction.

2. The integrated circuit device of claim 1, wherein the lower thin film includes undoped Si, SiB, SiN, or a combination thereof.

3. The integrated circuit device of claim 1, wherein a vertical thickness of the lower thin film in the third direction is not less than 8 nm.

4. The integrated circuit device of claim 1, wherein an upper surface of the lower thin film is at a same vertical level as an upper surface of the fin-type active region.

5. The integrated circuit device of claim 1, wherein an upper surface of the lower thin film is at a lower level than an upper surface of the fin-type active region.

6. The integrated circuit device of claim 1, wherein the second semiconductor pattern has a width greater than or equal to 30 nm in the second direction.

7. The integrated circuit device of claim 1, wherein the first semiconductor pattern has a width less than 30 nm in the second direction.

8. The integrated circuit device of claim 1, wherein an upper surface of the lower thin film is at least partially in contact with the first source/drain region.

9. The integrated circuit device of claim 1, wherein widths of the first semiconductor pattern and the second semiconductor pattern in the first direction are equal to each other.

10. The integrated circuit device of claim 1, wherein
the first and second source/drain regions each include a buffer layer, a main semiconductor layer, and a capping layer,
the buffer layers of the first source/drain region and the second source/drain region are in contact with the first and second semiconductor patterns, respectively,
the main semiconductor layers of the first source/drain region and the second source/drain region are on inner walls of the buffer layers of the first source/drain region and the second source/drain region, respectively, and
the capping layers of the first source/drain region and the second source/drain region are covering upper surfaces of the main semiconductor layers of the first source/drain region and the second source/drain region, respectively.

11. An integrated circuit device comprising:
a fin-type active region protruding from a substrate and extending in a first direction;
a first semiconductor pattern and a second semiconductor pattern spaced apart from each other in the first direction and a second direction, the second direction intersecting the first direction, the first semiconductor pattern and the second semiconductor pattern are above the fin-type active region;
a gate line extending in the second direction above the fin-type active region and surrounding the first and second semiconductor patterns;
a first source/drain region and a second source/drain region adjacent to the gate line above the fin-type active region, the first source/drain region being connected to the first semiconductor pattern, the second source/drain region being connected to the second semiconductor pattern;
a first lower thin film on the fin-type active region and below the first source/drain region; and
a second lower thin film on the fin-type active region and below the second source/drain region,
wherein the second semiconductor pattern has a greater width than the first semiconductor pattern in the second direction, and the first lower thin film has a greater thickness in a third direction intersecting the first direction and the second direction than the second lower thin film.

12. The integrated circuit device of claim 11, wherein the first and second lower thin films each include undoped Si, SiB, SiN, or a combination thereof.

13. The integrated circuit device of claim 11, wherein lower surfaces of the first and second lower thin films have a same vertical level.

14. The integrated circuit device of claim 11, wherein the first lower thin film has a vertical thickness not less than 8 nm, and the second lower thin film has a thickness in the third direction less than or equal to 8 nm.

15. The integrated circuit device of claim 11, wherein the second semiconductor pattern has a width greater than or equal to 30 nm in the second direction, and the first semiconductor pattern has a width less than 30 nm in the second direction.

16. The integrated circuit device of claim 11, wherein upper surfaces of the first and second lower thin films are at least partially in contact with the first and second source/drain regions, respectively.

17. The integrated circuit device of claim 11, wherein widths of the first semiconductor pattern and the second semiconductor pattern in the first direction are equal to each other.

18. An integrated circuit device comprising:
a fin-type active region protruding from a substrate and extending in a first direction;
a plurality of semiconductor patterns spaced apart from each other in the first direction and a second direction, the second direction intersecting the first direction, the plurality of semiconductor patterns are above the fin-type active region;
a gate line extending in the second direction above the fin-type active region and surrounding each of the plurality of semiconductor patterns;
a plurality of source/drain regions adjacent to the gate line above the fin-type active region and respectively connected to the plurality of semiconductor patterns; and
a lower thin film on the fin-type active region and below at least one of the plurality of source/drain regions,
wherein a semiconductor pattern adjacent to a source/drain region overlapping the lower thin film has a less width in the second direction than another semiconductor pattern not adjacent to the source/drain region overlapping the lower thin film.

19. The integrated circuit device of claim 18, wherein the lower thin film includes undoped Si, SiB, SiN, or a combination thereof.

20. The integrated circuit device of claim 18, wherein lower thin films are respectively below all of the plurality of source/drain regions, and vertical thicknesses of the lower thin films are different from each other.
